(19) United States
(12) Patent Application Publication
(10) Pub. No.: US 2006/0115769 A1
(43) Pub. Date: Jun. 1, 2006

(54) Correction solution and image correction process of planographic printing plate

(75) Inventor: Saburou Hiraoka, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KONICA MINOLTA MEDICAL & GRAPHIC, INC.

(21) Appl. No.: 11/283,697

(22) Filed: Nov. 22, 2005

(30) Foreign Application Priority Data
Nov. 30, 2004 (JP) JP2004-345726

(51) Int. Cl. G03F 7/00

(52) U.S. Cl. 430/300

(57) ABSTRACT

Provided is a correction solution accompanied with an image correction process used for a planographic printing plate, exhibiting an anti-stain property against fluctuation in printing conditions (such as change in ambient temperature, and so forth), in which not only stains on a printing plate surface can simply be removed stably, but also image portions can simply be corrected stably in a plate-making process. Also disclosed is a correction solution used for a planographic printing plate, containing a hydrophilic resin and/or hydrophilic particles, wherein the correction solution further contains solid particles having an average particle diameter of 0.5-5 μm.

This application claims priority from Japanese Patent Application No. 2004-345726 filed on Nov. 30, 2004, which is incorporated hereinto by reference.

### TECHNICAL FIELD

The present invention relates to a correction solution and an image correction process used for planographic printing plates.

### BACKGROUND

In the field of printing, a conventionally known plate-making process possessed the steps of imagewise exposing a planographic printing plate material (e.g., a PS plate) via originals and developing the exposed material with an alkali developer to form an image on the planographic printing plate material, whereby a planographic printing plate was obtained. Recently, as a computer spreads, a CTP (computer to plate) system has been developed in printing fields. Provided as a CTP planographic printing plate material type is a high sensitivity photopolymerization type, a silver halide DTR type, or an electrophotographic type. However, the silver halide DTR type and the electrophotographic type, employing a plastic film base material, have recently become popular due to customers' demand for a small number of prints.

An undesired image caused by stains and stripping traces of the originals, dust deposited during imagewise exposing, and scratches via handling in the plate-making process may be formed, when these planographic printing plates are used. An effective correction technique may be desired, since a part of the image or a word, for example, is possibly erased in some cases.

Various techniques have been disclosed as the correction technique for a planographic printing plate having a grained surface appearing in a PS plate or a high sensitivity photopolymerization type, and these techniques have already been utilized as a commercially available correction pen. It is commonly known that a conventional image correction process possesses the steps of dissolving undesired image portions or stains on a printing plate surface to remove them from the surface or covering them with a hydrophilic coating film. The process of dissolving undesired image portions or stains on a printing plate surface to remove them from the surface is generally used in a printing plate having a metal support, however, in a hydrophilic support (for example, a hydrophilic support in which a hydrophilic layer is provided on a paper sheet or a polyester film sheet), the hydrophilic layer may be largely dissolved in the correction solution to reveal the surface of the film sheets. As a countermeasure thereof, a process of covering undesired portions with a correction solution containing inorganic particles and a solvent with a hydrophilic coating film is proposed in Patent Document 1, for example. The process of covering undesired image portions with a correction solution containing a hydrophilic resin capable of coupling with a silane coupling agent is also disclosed in Patent document 2. Though these processes are surely capable of correcting images, only the correcting portions tend to be stained easily via fluctuation in printing conditions (such as change in surface temperature of a planographic printing plate, and the like) in the case of reduced dampening water. There is also a problem that after one touch of ink, stains can not be removed even though the amount of dampening water supply is increased.
(Patent Document 1) Japanese Patent O.P.I. Publication No. 2001-329191
(Patent Document 2) Japanese Patent O.P.I. Publication No. 2003-118261

### SUMMARY

It is an object of the present invention to provide a correction solution and an image correction process used for a planographic printing plate, exhibiting an anti-stain property against fluctuation in printing conditions (such as changes in ambient temperature, and the like), in which not only stains on a printing plate surface can be removed, but also image portions can be corrected, simply and stably in a plate-making process.

### BRIEF DESCRIPTION OF THE DRAWINGS

Embodiments will now be described, by way of example only, with reference to the accompanying drawing which are meant to be exemplary, not limiting, and wherein like elements numbered alike in several figures, in which:

FIG. 1 is a schematic cross-sectional view of a correction instrument (correction pen) used for a planographic printing plate.

### BRIEF DESCRIPTION OF THE PREFERRED EMBODIMENTS

The above object of the present invention is accomplished by the following structures.

(Structure 1) A correction solution for a planographic printing plate containing a hydrophilic resin and/or hydrophilic particles, wherein the correction solution further contains solid particles having an average particle diameter of 0.5-5 μm.

(Structure 2) The correction solution for a planographic printing plate of Structure 1, wherein the solid particles contain at least one selected from the group including silicon oxide, aluminum oxide, titanium oxide, and zirconium oxide.

(Structure 3) The correction solution for a planographic printing plate of Structure 1 or 2, wherein the solid particle content is 2-30% by weight, based on a total solid content in the correction solution.

(Structure 4) The correction solution for a planographic printing plate of any one of Structures 1-3, wherein the hydrophilic particles having a particle diameter of 1-100 nm contain at least one selected from the group including silicon oxide, aluminum oxide, titanium oxide, and zirconium oxide.

(Structure 5) The correction solution for a planographic printing plate of any one of Structures 1-4, wherein the hydrophilic particle content is 50-98% by weight, based on a total solid content in the correction solution.

(Structure 6) A process for correcting a planographic printing plate image in which the image is formed on a hydrophilic support, possessing the step of forming a hydrophilic coating film at a correcting image portion and its peripheral portion, wherein the hydrophilic coating film has protrusions of 0.1-5 μm in height.

(Structure 7) The process for correcting a planographic printing plate image of Structure 6, wherein the number of protrusions on the hydrophilic coating film is 500-10000 per mm².

While the preferred embodiments of the present invention have been described using specific terms, such description is for illustrative purposes only, and it is to be understood that changes and variations may be made without departing from the spirit or scope of the appended claims.

### DETAILED DESCRIPTION OF THE INVENTION

After considerable effort during intensive studies, the inventor has found out that image portions could simply be corrected stably with a correction solution containing solid particles having an average particle diameter of 0.5-5 μm, regardless of fluctuation in printing conditions.

Next, the present invention will be explained in detail.

A correction solution used for planographic printing plates of the present invention contains solid particles. Examples as solid particles include inorganic particles such as silicon oxide particles, aluminum oxide particles, zinc oxide particles, titanium oxide particles, zirconium oxide particles, and organic particles such as polymethyl acrylate particles, polystyrene particles, cellulose particles, and polytetrafluoroethylene particles. Specifically, inorganic particles such as silicon oxide particles, aluminum oxide particles, zinc oxide particles, titanium oxide particles, zirconium oxide particles are preferably used in view of high mechanical strength and excellent hydrophilicity obtained against heavy-duty printing.

It is preferred that each of solid particles has a particle diameter of 0.5-5 μm. In the case of the average particle diameter being less than 0.5 μm, a hydrophilic coating film formed via a correction solution is not capable of providing protrusions having a height of 0.1 μm or more, so that a water holding property at correcting portions is lowered, and stains are easily induced during printing. In the case of the average particle diameter exceeding 5 μm, protrusions having a height exceeding 5 μm are generated on a hydrophilic coating film formed via a correction solution, so that ink gets stuck with protrusions, and stains are also induced easily during printing. A correction solution containing such large particles has not been known so far.

Solid particles are cast on an electrically conductive sticky carbon tape, and the particles are observed employing a scanning electron microscope. A major axis length of each of 100 particles in an observation field is measured, and an average particle diameter of solid particles can be obtained from an average value of the 100 particles in the above measurement.

A height of protrusions on the hydrophilic coating film formed via a correction solution of the present invention means the average value obtained by measuring a height between a bottom surface of the coating film and a peak of protrusions at 10 spots by utilizing a convexoconcave profile of a hydrophilic coating film cross-sectional view, measured with a non-contact type surface profiler (RST/PLUS manufactured by WYKO Co., Ltd.).

The foregoing solid particle content is preferably 2-30% by weight, based on the total solid content in the correction solution. In the case of the solid particle content being less than 2% by weight, the number of protrusions on a hydrophilic coating film formed via a correction solution has been less than 500 per mm², so that a water holding property of the hydrophilic coating film can not be maintained, and in the case of the solid particle content exceeding 30% by weight, the number of protrusions on a hydrophilic coating film has exceeded 10000 per mm², so that no removal of stains is easy once ink has adhered.

The number of protrusions on a hydrophilic coating film formed via a correction solution of the present invention means the average value obtained by counting the number of protrusions per mm² in each of 10 observation fields by utilizing a height profile of a hydrophilic coating film, measured with a non-contact type surface profiler (RST/PLUS manufactured by WYKO Co., Ltd.) when the height of the hydrophilic coating film is not less than 0.1 μm, and portions having a diameter of not less than 0.2 μm are considered as protrusions.

A correction solution of the present invention contains a hydrophilic resin and/or hydrophilic particles.

Examples of the hydrophilic resin utilized for the present invention include an acryl resin, a polyvinyl resin, a polysaccharide, a polyurethane resin, a polyester resin, and a polyamine resin, each containing in the side chain one or more kinds and the plural number of a hydrophilic functional group selected from a carboxyl group, a phosphate group, a sulfonic acid group, an amino group or their salt group, a hydroxyl group, an amido group, and a polyoxyethylene group.

Examples as particles utilized for the present invention include hydrophilic particles having a particle diameter of 1-100 nm such as silicon oxide particles, aluminum oxide particles, zinc oxide particles, titanium oxide particles, and zirconium oxide particles. These materials are suitable to add high particle surface hydrophilicity and an anti-stain property during printing. In the case of a particle diameter of 1-100 nm, these particles are closely packed with each other because of the very small particle diameter, so that a favorable coating film can be formed to add mechanical strength during printing. When the foregoing hydrophilic particle content is 50-98% by weight, based on the total solid content in the correction solution, it is preferable that the features of hydrophilic particles in the present invention can be elicited. Provided is colloidal silica as the silicon oxide particles, for example, such as SNOWTEX series produced by Nissan Chemical Industries, Ltd. or LUDOX series produced by Toray Industries, Inc. ALUMINASOL produced by Nissan Chemical Industries, Ltd. can also be utilized as the aluminum oxide particles for the purpose of the present invention.

Hydrophilic particles are cast on an electrically conductive sticky carbon tape, and the particles are observed employing a 100000-power scanning electron microscope S-8000 (manufactured by Hitachi, Ltd.). A major axis length of each of 100 particles in an observation field is measured, and in the present invention an average value obtained via measuring of the 100 particles is specified to be the average particle diameter.

The correction solution in the present invention may contain a cross-linking agent in order to increase film strength. Examples of the cross-linking agent include a melamine resin, an isocyanate compound, a polyamide resin, a polyamine resin, and a metal alkoxide. The cross-linking agent content of the correction solution is preferably 0-5%, based on the total solid content in the correction solution.

A solvent used for the correction solution in the present invention is preferably water or water-soluble solvents such as lower alcohols (for example, methanol, ethanol and isopropyl alcohol), acetone, methyl cellosolve, ethyl cellosolve, ethylene glycol, diethylene glycol, and propylene glycol.

It is a feature in the image correction process of a planographic printing plate of the present invention that a hydrophilic coating film is formed at a correcting portion on a hydrophilic support via coating and subsequently drying a planographic printing plate correction solution.

It is provided as a process of coating a planographic printing plate correction solution that a coating process is conducted while thinly coating the correction solution employing a swab or a paint-brush.

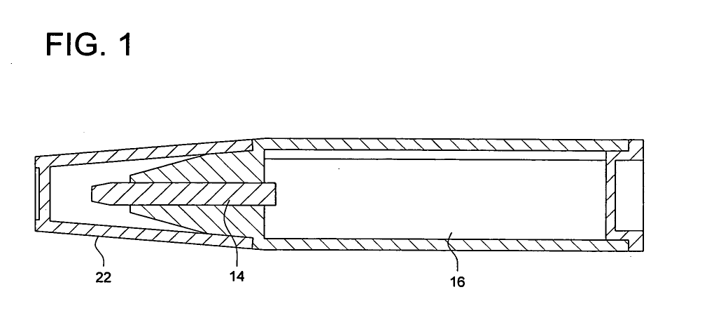

A correction instrument (such as a correction pen) as shown in FIG. 1 used for a planographic printing plate can also be utilized. In the figure, numeral 16 designates a receptacle portion to store the correction solution. Numeral 14 designates a felt portion, through which the stored correction solution is drawn to its tip portion. In the case of correcting by using this correction pen, the correction solution at the felt tip portion is placed in contact with the image portion to be corrected and its peripheral portion on a planographic printing plate, and the correction is made via coating while thinly coating the solution at the felt tip portion. In addition, numeral 22 designates a cap of the correction instrument.

It is provided as a process of drying a coated planographic printing plate correction solution that an air drying process or a drying process with blasts of hot air is conducted.

[Planographic Printing Plate]

Various planographic printing plates are provided as the planographic printing plate to which an image correction solution, an image correction process and an image correction instrument in the present invention can be applied. Provided, for example, is a planographic printing plate in which an image is formed on a hydrophilic support constituted by a surface-roughened aluminum plate, or on a hydrophilic support which is a flexible support, made of polyethylene terephthalate or a paper sheet, having thereon a coated hydrophilic layer. An attention is focused on stability in the image correction process, and effectively usable is, specifically, a planographic printing plate having a hydrophilic support which is a flexible support, having thereon a coated hydrophilic layer, such as a plastic support or so forth, to which an exposed support may be concerned during correcting.

A usable planographic printing plate for the present invention and a planographic printing plate material to prepare the planographic printing plate are described in Japanese Patent O.P.I. Publication Nos. 8-230345, 2001-187489, 2000-225780, 2000-229480, and 2001-96170.

### EXAMPLE

Next, the present invention will be explained employing examples, but the present invention is not limited thereto. In addition, a symbol “%” in examples represents “% by weight”, unless otherwise noted.

### Example

[Preparation of Correction Solution]

A correction solution with the following composition was prepared. Incidentally, particles within a correction solution are cast on the foregoing electrically conductive sticky carbon tape, and the particles are observed employing a scanning electron microscope S-8000 (manufactured by Hitachi, Ltd.). A major axis length of each of 100 particles in an observation field is measured, and an average value obtained via measuring of the 100 particles is specified to be the average particle diameter.

| (CORRECTION SOLUTION 1) | | |
|---|---|---|
| Colloidal silica (SNOETEX XS, | 72.75 | parts by weight |
| 30% solid content and 8 nm | | |
| in average particle diameter, | | |
| produced by Nissan Chemical | | |
| Industries, Ltd) | | |
| Silica particle (SILTON AMT08L | 0.45 | parts by weight |
| 0.6 μm in average particle diameter, | | |
| produced by Mizusawa Industrial | | |
| Chemicals, Ltd.) | | |
| Pure water | 26.80 | parts by weight |
| (CORRECTION SOLUTION 2) | | |
| Colloidal silica (SNOETEX XS, | 69.75 | parts by weight |
| 20% solid content and 8 nm | | |
| in average particle diameter, | | |
| produced by Nissan Chemical | | |
| Industries, Ltd) | | |
| Silica particle (SILTON JC30, | 1.05 | parts by weight |
| 3.0 μm in average particle diameter, | | |
| produced by Mizusawa Industrial | | |
| Chemicals, Ltd.) | | |
| Pure water | 29.20 | parts by weight |
| (CORRECTION SOLUTION 3) | | |
| Colloidal silica (SNOETEX XS, | 67.75 | parts by weight |
| 20% solid content and 8 nm | | |
| in average particle diameter, | | |
| produced by Nissan Chemical | | |
| Industries, Ltd) | | |
| Silica particle (SILTON JC30, | 2.25 | parts by weight |
| 3.0 μm in average particle diameter, | | |
| produced by Mizusawa Industrial | | |
| Chemicals, Ltd.) | | |
| Pure water | 34.0 | parts by weight |
| (CORRECTION SOLUTION 4) | | |
| Colloidal silica (SNOETEX XS, | 56.25 | parts by weight |
| 20% solid content and 8 nm | | |
| in average particle diameter, | | |
| produced by Nissan Chemical | | |
| Industries, Ltd) | | |
| Silica particle (SILTON JC30, | 3.75 | parts by weight |
| 3.0 μm in average particle diameter, | | |
| produced by Mizusawa Industrial | | |
| Chemicals, Ltd.) | | |
| Pure water | 40.0 | parts by weight |
| (CORRECTION SOLUTION 5) | | |
| Colloidal silica (Methanol | 63.75 | parts by weight |
| colloidal silica, 20% solid content | | |
| and 10 nm in average particle | | |
| diameter, produced by Nissan | | |
| Chemical Industries, Ltd) | | |
| Silica particle (SILTON JC50, | 2.25 | parts by weight |
| 5.0 μm in average particle diameter, | | |
| produced by Mizusawa Industrial | | |
| Chemicals, Ltd.) | | |
| Ethanol | 14.0 | parts by weight |
| Pure water | 20.0 | parts by weight |
| (CORRECTION SOLUTION 6) | | |
| Colloidal silica (Methanol | 60.00 | parts by weight |
| colloidal silica, 20% solid content | | |
| and 10 nm in average particle | | |
| diameter, produced by Nissan | | |
| Chemical Industries, Ltd) | | |
| Silica particle (SILTON JC70, | 3.0 | parts by weight |
| 7.0 μm in average particle diameter, | | |
| produced by Mizusawa Industrial | | |
| Chemicals, Ltd.) | | |
| Ethanol | 17.0 | parts by weight |
| Pure water | 20.0 | parts by weight |
| (CORRECTION SOLUTION 7) | | |
| Colloidal silica (SNOETEX XS, | 45.0 | parts by weight |
| 20% solid content and 8 nm | | |
| in average particle diameter, | | |
| produced by Nissan Chemical | | |
| Industries, Ltd) | | |
| Silica particle (Colloidal silica, | 15.0 | parts by weight |
| 40% solid content and 189 nm | | |
| in average particle diameter, | | |
| produced by Mizusawa Industrial | | |
| Chemicals, Ltd.) | | |
| Pure water | 40.0 | parts by weight |
| (CORRECTION SOLUTION 8) | | |
| Colloidal silica (Methanol | 70.0 | parts by weight |
| colloidal silica, 20% solid content | | |
| and 10 nm in average particle | | |
| diameter, produced by Nissan | | |
| Chemical Industries, Ltd) | | |
| Ethanol | 20.0 | parts by weight |
| Pure water | 10.0 | parts by weight |

Obtained correction solutions 1-8 were stored in a correction instrument (correction pen) used for a planographic printing plate in FIG. 1.

[Preparation of Planographic Printing Plate Material]

(Preparation of Hydrophilic Support)

Each of a hydrophilic subbing layer coating liquid and a hydrophilic layer coating liquid, constituted by the following composition, was mixed by a homogenizer for 15 minutes to prepare each coating liquid. A hydrophilic subbing layer coating liquid was coated on a 175 μm thick PET film sheet subjected to hydrophilic adhesion increasing treatment employing a wire bar, so as to obtain a coating amount of 3 g/m², and dried at 100° C. for one minute. Next, a hydrophilic layer coating liquid was coated employing a wire bar so as to obtain a coating amount of 1 g/m², and dried at 100° C. for one minute to prepare a hydrophilic support (plastic support).

<HYDROPHILIC SUBBING LAYER COATING LIQUID>

| | | |
|---|---|---|
| Colloidal silica (SNOETEX XS, | 75 | parts by weight |
| 20% solid content and 8 nm | | |
| in average particle diameter, | | |
| produced by Nissan Chemical | | |
| Industries, Ltd) | | |
| Colloidal silica (SNOETEX ZL, | 2.5 | parts by weight |
| 40% solid content and 70-100 nm | | |
| in average particle diameter, | | |
| produced by Nissan Chemical | | |
| Industries, Ltd) | | |
| Silica particle (SILTON JC40, | 5 | parts by weight |
| 4.0 μm in average particle diameter, | | |
| produced by Mizusawa Industrial | | |
| Chemicals, Ltd.) | | |
| MF Black 4500 (Fe—Mn—Cu composite metal | 15 | parts by weight |
| oxide, 40% aqueous dispersion, produced | | |
| by Dainichi Seika Kogyo Co., Ltd.) | | |
| Mineral colloid MO (MONTMORILLONITE, | 2 | parts by weight |
| produced by Wilber Ellis Co.) | | |
| FZ2161 (silicon-containing surfactant, | 0.5 | parts by weight |
| produced by Nippon Unicar Co., Ltd.)] | | |
| <HYDROPHILIC LAYER COATING LIQUID> | | |
| Colloidal silica (SNOETEX XS, | 70 | parts by weight |
| 20% solid content and 8 nm | | |
| in average particle diameter, | | |
| produced by Nissan Chemical | | |
| Industries, Ltd) | | |
| Colloidal silica (SNOETEX PSM, | 12.5 | parts by weight |
| necklace-shaped colloidal silica, | | |
| 20% solid content and 80-150 nm | | |
| in average particle diameter, | | |
| produced by Nissan Chemical | | |
| Industries, Ltd) | | |
| Silica particle (SILTON JC40, | 5 | parts by weight |
| 4.0 μm in average particle diameter, | | |
| produced by Mizusawa Industrial | | |
| Chemicals, Ltd.) | | |
| MF Black 4500 (Fe—Mn—Cu composite metal | 15 | parts by weight |
| oxide, 40% aqueous dispersion, produced | | |
| by Dainichi Seika Kogyo Co., Ltd.) | | |
| Mineral colloid MO (MONTMORILLONITE, | 2 | parts by weight |
| produced by Wilber Ellis Co.) | | |
| FZ2161 (silicon-containing surfactant, | 0.5 | parts by weight |
| produced by Nippon Unicar Co., Ltd.) | | |

(COATING OF IMAGE FORMATION LAYER)

An image formation layer coating liquid with the following composition was coated on the above-prepared hydrophilic layer employing a wire bar, so as to obtain a coating amount of 0.5 g/m², and dried at 70° C. for one minute. It was further subjected to heat treatment at 50° C. for 24 hours to acquire a planographic printing plate material.

<IMAGE FORMATION LAYER COATING LIQUID>

| | |
|---|---|
| Hi-Disperser A-118 (Aqueous CARNAUBA | 17 parts by weight |
| wax particle dispersion, 40% solid content | |
| and 0.5 μm in average particle diameter, | |
| produced by Gifu Shellac Co., Ltd.) | |
| Hi-Disperser A-206 (Aqueous MICROCRYSTALIN | 6 parts by weight |
| wax particle dispersion, 40% solid content | |
| and 0.6 μm in average particle diameter, | |
| produced by Gifu Shellac Co., Ltd.) | |
| AQUALIC DL522 (30% aqueous solution | 3 parts by weight |
| of polyacrylic acid soda, produced | |
| by Nippon Shokubai Co., Ltd.) | |
| Pure water | 74 parts by weight |

[Preparation of Planographic Printing Plate]

The resulting planographic printing plate material was mounted on a drum of a plate setter equipped with a 830 nm semiconductor laser having an output power of 300 mW and a beam diameter of 32 μm (1/e²), wherein the drum rotation number was adjusted so that exposure energy intensity on the printing surface was 300 mJ/cm², and images including a solid patch image of 5 mm×5 mm in size were exposed to laser light.

Subsequently, the exposed planographic printing plate material was mounted on a plate cylinder of an off-set printing press LITHRONE 20, and printing was carried out employing a 2% aqueous solution of ASTROMARK 3 (produced by Nikken Kagaku Kenkyusyo Co., Ltd.) as a dampening solution, and Hyunity Magenta (produced by Toyo Ink Manufacturing Co.) as the printing ink. The planographic printing plate material was developed on the plate cylinder, and excellent prints were obtained after printing 5 copies.

[Evaluation of Correction Solution]

After a solid patch image and its peripheral portion of the resulting planographic printing plate were coated employing a correction pen in which the above-prepared correction solution was stored, and were dried naturally for 5 minutes, the height and the number of protrusions on a hydrophilic coating film at the correction solution coating portion were measured.

A height of protrusions on the hydrophilic coating film formed via a correction solution of the present invention means the average value obtained by measuring a height between a bottom surface of the coating film and a peak of protrusions at 10 spots by utilizing a convexoconcave profile of a hydrophilic coating film cross-sectional view, measured with a non-contact type surface profiler (RST/PLUS manufactured by WYKO Co., Ltd.), whereby the height of protrusions is determined by the average value. The number of protrusions on a hydrophilic coating film formed via a correction solution of the present invention means the average value obtained by counting the number of protrusions per mm² in each of 10 observation fields by utilizing a height profile of a hydrophilic coating film, measured with a non-contact type surface profiler (RST/PLUS manufactured by WYKO Co., Ltd.) when the height of the hydrophilic coating film is not less than 0.1 μm, and portions having a diameter of not less than 0.2 μm are considered as protrusions, whereby the number of protrusions is determined by the average value.
A: A solid patch image is perfectly erased, so that density of a paper sheet at a print correcting portion is the same density as at a non-image portion.
B: A solid patch image is possibly erased, but it is not erased sufficiently since density of a paper sheet at a print correcting portion is higher than at a non-image portion.
C: A solid patch image is not erased entirely, so that stains have been generated.
   [Stain Evaluation 1]

When an amount of dampening water supply is gradually reduced during printing, percentage of the amount of dampening water consumed before stains are generated from correcting portions is specified as an indicator of being easy to generate stains at correcting portions. It is meant that the less the percentage, the stronger the anti-stain property at correcting portions is.

[Stain Evaluation 2]

After ink adhered evenly to a planographic printing plate via an ink roller, printing was subsequently carried out, and the number of copies consumed before stains at correcting portions are removed is counted. It is meant that the less the number of copies, the higher the anti-stain property is.

Evaluation results are shown in Table 1.

TABLE 1

| | | | Height of | | | | | |
|---|---|---|---|---|---|---|---|---|
| | | | protrusions | | | | | |
| | Solid | Solid | on | Number | | | Stain | |
| | particle | particle | hydrophilic | of | | Stain | evaluation 2 | |
| Correction | diameter | content | coating | protrusions | | evaluation 1 | (Number | |
| solution No. | (μm) | (%) *1 | film (μm) | per mm² | Erasability | (%) | of copies) | Remarks |
| 1 | 0.6 | 3 | 0.3 | 2873 | A | 24 | 25 | Pres. inv. |
| 2 | 3.0 | 7 | 1.7 | 3011 | A | 24 | 25 | Pres. inv. |
| 3 | 3.0 | 15 | 2.1 | 7224 | A | 19 | 20 | Pres. inv. |
| 4 | 3.0 | 25 | 2 | 13408 | A | 24 | 75 | Pres. inv. |
| 5 | 5.0 | 15 | 4.1 | 3675 | A | 20 | 20 | Pres. inv. |
| 6 | 7.0 | 0 | 6.3 | 1317 | B | 28 | 100 | Comp. ex. |
| 7 | 0.19 | 0 | 0.1 | 25841 | B | 26 | 200 | Comp. ex. |
| 8 | — | 0 | — | — | C | 50 | 1000 | Comp. ex. |
| | | | | | | | or more | |

Pres. inv.: Present invention,
Comp. ex.: Comparative example,
*1: Average solid particle diameter of 0.5-5 μm

It is to be understood from Table 1 that an image correction can be made with an anti-stain property against fluctuation in printing conditions, when a correction solution used for a planographic printing plate contains solid particles of 2-20% by weight, having an average particle diameter of 0.5-5.0 μm, and a hydrophilic coating film processes protrusions of 0.1-5.0 μm in height and the number of protrusions of 500-10000 per mm².

[Effect of the Invention]

In the present invention, provided are a correction solution and an image correction process used for a planographic printing plate, exhibiting an anti-stain property against fluctuation in printing conditions (change in increase of an amount of dampening water coming up to the surface of a planographic printing plate, associated with change in ambient temperature), in which not only stains on a printing plate surface can simply be removed stably, but also image portions can simply be corrected stably in a plate-making process.

What is claimed is:

1. A correction solution for a planographic printing plate containing a hydrophilic resin and/or hydrophilic particles,
wherein the correction solution further contains solid particles having an average particle diameter of 0.5-5 μm.

2. The correction solution for a planographic printing plate of claim 1,
wherein the solid particles contain at least one selected from the group including silicon oxide, aluminum oxide, titanium oxide, and zirconium oxide.

3. The correction solution for a planographic printing plate of claim 1,
wherein the solid particle content is 2-30% by weight, based on a total solid content in the correction solution.

4. The correction solution for a planographic printing plate of claim 1,
wherein the hydrophilic particles having a particle diameter of 1-100 nm contain at least one selected from the group including silicon oxide, aluminum oxide, titanium oxide, and zirconium oxide.

5. The correction solution for a planographic printing plate of claim 1,
wherein the hydrophilic particle content is 50-98% by weight, based on a total solid content in the correction solution.

6. A process for correcting a planographic printing plate image in which the image is formed on a hydrophilic support, comprising the step of forming a hydrophilic coating film at a correcting image portion and its peripheral portion,
wherein the hydrophilic coating film has protrusions of 0.1-5 μm in height.

7. The process for correcting a planographic printing plate image of claim 6,
wherein the number of protrusions on the hydrophilic coating film is 500-10000 per mm².
